(19) United States
(12) Patent Application Publication
(10) Pub. No.: US 2025/0167513 A1
(43) Pub. Date: May 22, 2025

(54) METHOD AND APPARATUS FOR CONTROLLING NODE VOLTAGES DURING START-UP OF A DRIVER CIRCUIT TO FACILITATE BIASING OF THE DRIVER CIRCUIT

(71) Applicant: MACOM Technology Solutions Holdings, Inc., Lowell, MA (US)

(72) Inventors: Peter Considine, Lowell, MA (US); Nicolas Nodenot, Lowell, MA (US)

(21) Appl. No.: 18/518,266

(22) Filed: Nov. 22, 2023

(51) Int. Cl. H01S 5/042; H01S 5/183

(52) U.S. Cl. CPC H01S 5/042; H01S 5/183

(57) ABSTRACT

Voltages and currents associated with a driver circuit associated with a diode can be controlled during start up of the driver circuit. The driver circuit can comprise transistors that can satisfy a defined bandwidth specification in connection with driving an electrical signal for the diode. During start up, start-up controller component can control voltage levels applied to gates or backgates of transistors to maintain operating voltage levels associated with transistors at or below a defined voltage level as bias current level is incrementally increased to target bias current level, and/or start-up reference voltage level is incrementally increased to facilitate incrementally increasing an anode voltage level of an anode voltage associated with the diode. The driver circuit can supply the electrical signal to the diode based on the bias current, which can facilitate operation of the driver circuit.

### 1. FIELD OF THE INVENTION

The innovation relates generally to electronic circuitry and in particular to a method and apparatus for controlling node voltages during start-up of a driver circuit to facilitate biasing of the driver circuit.

### 2. BACKGROUND OF THE INVENTION

Driver circuits, such as, such as vertical-cavity surface-emitting laser (VCSEL) or other type of current mode driver circuits, can be utilized to drive, control, or facilitate operation of electrical or electronic components or systems, such as VCSEL diodes or other type of component or system. Depending on the specifications of the component or system to be driven or controlled by a driver circuit, the driver circuit may have to be structured to meet certain specifications, such as with regard to bias current, bandwidth, speed, or other specification, in order to suitably drive, control, or facilitate operation of the associated electrical or electronic components or systems.

The above-described description is merely intended to provide a contextual overview relating to existing technology and is not intended to be exhaustive.

### SUMMARY

The following presents a simplified summary in order to provide a basic understanding of some aspects described herein. This summary is not an extensive overview of the disclosed subject matter. It is intended to neither identify key or critical elements of the disclosure nor delineate the scope thereof. Its sole purpose is to present some concepts in a simplified form as a prelude to the more detailed description that is presented later.

In some embodiments, the disclosed subject matter can comprise a system that can facilitate control of biasing of a driver circuit. The system can comprise the driver circuit that can control an electrical signal supplied to a diode component, wherein the driver circuit can comprise a group of transistors that satisfy a defined bandwidth specification in connection with driving the electrical signal. The system also can comprise a start-up controller component that, during a start-up mode associated with powering up of the driver circuit, can control respective voltage levels of respective voltages applied to respective transistors of the group of transistors to have respective operating voltage levels of operating voltages associated with the respective transistors not be higher than a defined voltage level as at least a bias current level of a bias current of the driver circuit is incrementally increased to a target bias current level.

In certain embodiments, the disclosed subject matter can comprise a method that can facilitate controlling biasing of a driver circuit. The method can comprise: during a start-up mode associated with powering up of the driver circuit, controlling respective voltage levels of respective voltages applied to respective transistors to maintain respective operating voltage levels of operating voltages associated with the respective transistors at or below a defined voltage level as at least a bias current level of a bias current of the driver circuit is incrementally increased to a target bias current level, wherein the driver circuit can comprise the respective transistors that satisfy a defined bandwidth specification in connection with driving an electrical signal. The method also can comprise supplying, by the driver circuit, the electrical signal to a diode component.

In still other embodiments, the disclosed subject matter can comprise a non-transitory machine-readable medium, comprising executable instructions that, when executed by a processor, facilitate performance of operations. The operations can comprise: during a start-up mode associated with powering up of a driver circuit, managing respective voltage levels of respective voltages applied to the respective transistors to maintain respective operating voltage levels of operating voltages associated with the respective transistors at or less than a defined threshold voltage level as a bias current level of a bias current of the driver circuit is incrementally increased to a target bias current level or a start-up reference voltage level of a start-up reference voltage is incrementally increased to facilitate incrementally increasing an anode voltage level of an anode voltage associated with an anode associated with the diode component, wherein the driver circuit can comprise the respective transistors that satisfy a defined bandwidth specification in connection with driving an electrical signal. The operations also can comprise supplying, by the driver circuit, the electrical signal to a diode component.

The following description and the annexed drawings set forth in detail certain illustrative aspects of the subject disclosure. These aspects are indicative, however, of but a few of the various ways in which the principles of various disclosed aspects can be employed and the disclosure is intended to include all such aspects, variations, modifications, and their equivalents. Other advantages and novel features will become apparent from the following detailed description when considered in conjunction with the drawings.

### BRIEF DESCRIPTION OF THE DRAWINGS

FIG. 1A illustrates a block diagram of a non-limiting example system that can desirably control incrementally adjusting a bias current to a target bias current level.

FIG. 1B illustrates a block diagram of a non-limiting example system that can desirably control incrementally adjusting a bias current to a target bias current level with divider components.

FIG. 2 depicts a diagram of an example pulse amplitude modulation 4-level (PAM4) eye diagram relating to the driver circuit, in accordance with various aspects and embodiments.

FIG. 3A illustrates a diagram of an example cascode component comprising transistors in a desired cascode arrangement, in accordance with various aspects and embodiments of the disclosed subject matter.

FIG. 3B illustrates a diagram of an example cascode component comprising transistors in a desired cascode arrangement with resistors switchable to ground, in accordance with various aspects and embodiments of the disclosed subject matter.

FIG. 4 illustrates a flow chart of an example method that can desirably control incrementally increasing a bias current to a target bias current level for a driver circuit associated with a diode component during start-up of the driver circuit, in accordance with various aspects and embodiments of the disclosed subject matter.

FIG. 5 depicts a flow chart of another example method that can desirably control incrementally increasing a bias current to a target bias current level for a driver circuit associated with a diode component during start-up of the driver circuit, in accordance with various aspects and embodiments of the disclosed subject matter.

FIG. 6 illustrates a flow chart of an example method for bias voltage control with associated modulation current level setup.

### DETAILED DESCRIPTION

The disclosure herein is described with reference to the drawings, wherein like reference numerals are used to refer to like elements throughout. In the following description, for purposes of explanation, numerous specific details are set forth in order to provide a thorough understanding of the disclosed subject matter. It may be evident, however, that various disclosed aspects can be practiced without these specific details. In other instances, well-known structures and devices are shown in block diagram form in order to facilitate describing the disclosed subject matter.

In some existing approaches for driver circuits, such as, but not limited to, vertical-cavity surface-emitting laser (VCSEL) or other type of current mode driver circuits, such drivers operated at relatively lower frequencies and/or did not have to have high current biasing, and therefore, such drivers operated at relatively lower voltages. Also, with regard to such existing driver circuits, bipolar complementary metal-oxide-semiconductor (CMOS) technologies (bi-CMOS technologies) were used, with bipolar transistors capable of satisfying bandwidth and high voltage requirements for some existing driver circuits. In such existing driver circuits, the drivers operated at relatively lower data frequencies and/or did not have to have high current biasing, and therefore, operated at relatively lower voltages.

In some instances, the manufacturing technology or process selected or required for an integrated circuit must be suitable for both digital logic and analog circuitry. The technology chosen for a given product depends also on the speed, density and power consumption of digital logic circuitry. Therefore, a technology may be chosen which is fast for digital logic but does not provide high performance bipolar transistors, and therefore the analog circuit designer is obliged to use fast but low-voltage CMOS transistors for analog functions as a compromise, which can add complexity in the case of high-voltage driver circuitry.

In other situation, it can be desirable (e.g., wanted, required, or optimal) for a high speed, current mode driver circuit, such as, for example, a VCSEL driver, to operate at bias current sufficiently high enough to achieve a desired (e.g., desirably high) bandwidth of data to be transmitted. This can impose a relatively high operating voltage on the electrical driver circuit, where such operating voltage can be in, for example, a 3 volt (V) to 5 V range. With regard to such driver circuits, it can be desirable to select or utilize, for example, a fine gate length CMOS technology due in part to its desirably high density and speed capabilities, as the fine gate length CMOS transistors are often the only candidates that can be capable of satisfying (e.g., meeting) the high bandwidth specifications (e.g., requirements) that can be desired (e.g., wanted, needed, or optimal) to drive the output signal of the driver circuit. However, these fine gate length CMOS transistors typically can be incapable of operating at voltages greater than 1 V, and also typically have to be stacked in series (e.g., stacked in series in such a way that the operating voltage of an individual transistor does not exceed the maximum operating voltage (e.g., 1 V) for that transistor), and, as a result, it can be desirable (e.g., wanted, needed, required, or optimal) to have accurate, predefined gate and back-gate bias voltages to be applied to such fine gate length CMOS transistors in order to pass reliability and not exceed the maximum operating voltage for the fine gate length CMOS transistors.

When the driver circuit has to be set to a biasing target (e.g., user defined biasing target) at power-on of the driver circuit, or when the biasing target is modified, device or driver circuit failure can occur due to reliability violations (e.g., due to maximum operating voltage for the fine gate length CMOS transistors being exceeded), unless internal node voltages of the driver circuit are well controlled during these transients associated with setting a biasing target at power-on of the driver circuit or modifying the biasing target, to facilitate keeping the operating voltage for the fine gate length CMOS transistors from exceeding the maximum operating voltage. Also, if the driver control loop of the driver circuit is configured to set bias current but does not bias voltage directly, transient voltage violations can occur (e.g., maximum operating voltage for the fine gate length CMOS transistors can be exceeded causing device or driver circuit failure).

Also, voltage accuracy for many nodes of the driver circuit can be achieved utilizing digital-to-analog converters (DACs). If setting of internal node voltages of the driver circuit involves programming numerous DACs through a serial interface, tracking reliability specifications (e.g., reliability requirements) during these transients associated with the driver circuit can be difficult or virtually impossible.

The disclosed subject matter can overcome these and other problems and deficiencies of existing systems, devices, and techniques relating to driver circuits.

In accordance with various embodiments, the disclosed subject matter can comprise a system that can desirably control voltages and currents associated with a driver circuit associated with a diode, or any other current mode load circuit, during start up (e.g., powering on or up) of the driver circuit or other transient conditions associated with the driver circuit. The system can comprise a start-up controller component that can be associated with (e.g., electrically and communicatively connected to) the driver circuit and can facilitate controlling voltages and currents associated with the driver circuit during startup of the driver circuit and setting of bias targets and during other transient conditions (e.g., modification of a bias target or powering down of the driver circuit). The driver circuit can operate in start-up mode and mission mode (e.g., a steady state or normal operating mode). In accordance with various embodiments, the driver circuit can be a current mode driver circuit or a VCSEL driver circuit. The driver circuit can be associated with a diode component. In some embodiments, the diode component can be or can comprise a VCSEL diode.

The driver circuit can comprise transistors that can satisfy a defined bandwidth specification and/or other desired specifications (e.g., high density, high speed, and/or other specifications) in connection with driving an electrical signal for the diode. In some embodiments, the transistors can be fine gate length CMOS transistors. In certain embodiments, respective transistors and respective other transistors can be stacked in series in relation to each other or can be arranged (e.g., in a cascode arrangement) in relation to each other to form respective cascode components. The cascode components, comprising the transistors, can facilitate driving a desired electrical signal (e.g., output electrical signal) that can be provided to the diode component to enable the diode component to desirably operate (e.g., conduct, communicate, or otherwise operate).

During start-up of the driver circuit, the start-up controller component can control voltage levels applied to respective gates or respective backgates of the respective transistors to maintain operating voltage levels associated with the transistors at or below a defined voltage level (e.g., a threshold or threshold maximum operating voltage level) as the bias current level is incrementally increased to a target bias current level, and/or a start-up reference voltage level is incrementally increased to facilitate incrementally increasing an anode voltage level of an anode voltage associated with the diode component. For instance, when the driver circuit is in start-up mode (e.g., switched to start-up mode), a driver feedback loop of the driver circuit can be reconfigured as a voltage follower such that the anode voltage level of the anode voltage of the anode associated with the diode component can track (e.g., be equal or substantially equal to) the start-up reference voltage level of the start-up reference voltage, which can be a programmable voltage that can be programmed or set using a DAC. This can allow the anode voltage level to be incrementally increased at the accuracy of the start-up reference voltage level, as the start-up reference voltage level is incrementally increased by the start-up controller component, in a direct current (DC) manner. This can allow internal voltages of the driver circuit to be desirably set (e.g., incrementally increased or decreased at each setting of the anode voltage target DAC setting) through a serial interface of the start-up controller component in a controlled manner. In one embodiment, the driver circuitry may require a time delay between setting of one operating point and the next operating point for voltage and current settling. This can be built into the sequencer program or other control logic/time structure. Likewise, the start-up controller component can set reference currents, via internal DACs of the start-up controller component, wherein the reference currents can set or facilitate setting the bias current and/or modulation current of the driver circuit.

In some embodiments, the start-up controller component can comprise a comparator component (e.g., an internal voltage-mode comparator) that can compare the start-up reference voltage level (which can be incrementally increased) to a reference voltage level (e.g., reference voltage level of an internal reference voltage) of the driver circuit. When the bias current through the anode associated with the diode component reaches (e.g., satisfies or meets) or exceeds the target reference bias current level (e.g., for this start-up iteration of the start-up sequence), the comparator component can trip (e.g., can transition from a 0 output value to a 1 output value), due to the reference voltage level being greater than the start-up reference voltage level, as the bias current at the anode exceeding the reference bias current can cause the reference voltage level to be greater than the start-up reference voltage level. If, after sufficient time for the circuit to settle, the comparator has not tripped, then the bias can again be incremented. This process can repeat. For example, after sufficient settling time, the comparator again compares the anode bias current to the target reference. The start-up controller component can continue or repeat this iterative start-up sequence for a number of iterations until the driver circuit satisfies (e.g., reaches, meets, or attains) the target bias current associated with mission mode operation of the driver circuit.

During each of these iterations of the start-up sequence, in connection with the start-up controller component incrementally increasing the start-up reference voltage level, the start-up controller component can set or program respective DACs to adjust respective voltage levels of respective voltages applied to the respective gates or the respective backgates of the respective transistors and respective current levels of respective currents (e.g., reference bias current of the driver circuit). The start-up controller component can control the respective voltage levels of the respective voltages applied to the respective gates or the respective backgates of the respective transistors to maintain the operating voltage levels associated with the respective transistors at or below the defined voltage level (e.g., the threshold or threshold maximum operating voltage level).

Once the start-up controller component determines that the target bias current is satisfied, by detection of a change in state of the startup comparator when the reference bias current has been set at the target reference bias current level, the start-up controller component can switch the operating mode of the driver circuit from start-up mode to mission mode, which can include reconfiguring the driver control (e.g., feedback and control) loop (e.g., by switching the loop amplifier feedback nodes), without changing biasing conditions associated with the driver circuit, and the driver circuit can operate in mission mode and desirably drive or facilitate operation of the diode component. The switching of the driver circuit from the start-up mode to mission mode may involve incurring a minimal but acceptable, amount of glitches that will not negatively impact performance of the driver circuit or diode component, since neither the anode voltage nor current biasing should change as a result of switching of the driver circuit from the start-up mode to mission mode. The start-up controller component, employing the iterative and controlled start-up sequence, can desirably allow a low initial current bias target to be accurately set so as not to cause reliability issues associated with the driver circuit while allowing the driver circuit to start conducting.

These and other aspects and embodiments of the disclosed subject matter will now be described with respect to the drawings.

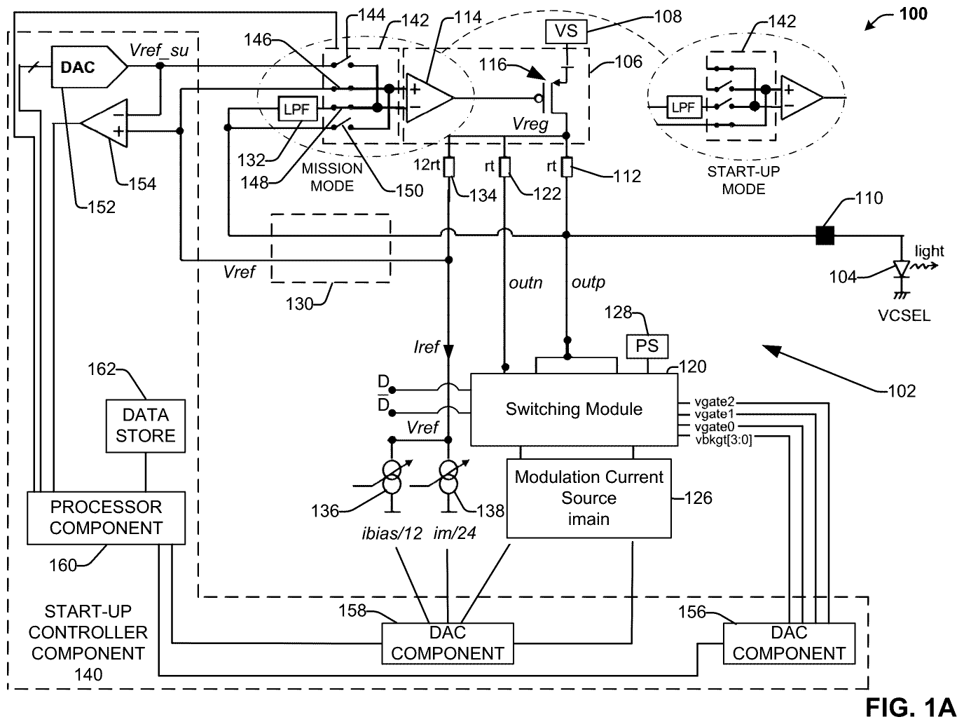

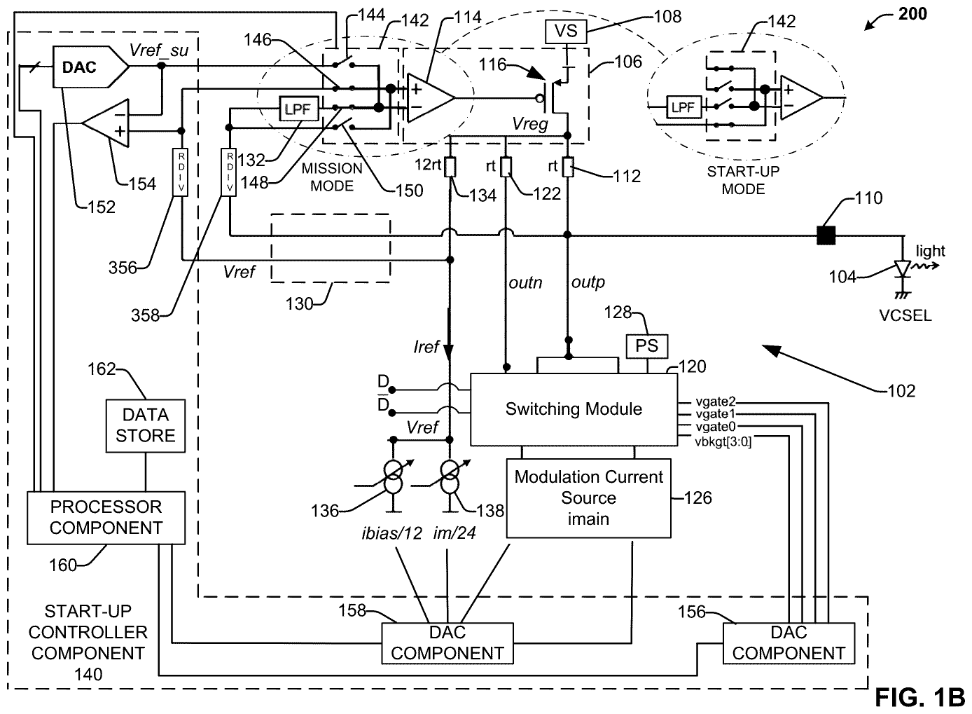

FIG. 1 illustrates a block diagram of a non-limiting example system 100 that can control incrementally adjusting a bias current to a target bias current level and/or set a modulation current for a driver circuit associated with a diode component, during start-up or other transient condition associated with the driver circuit, during start-up of the driver circuit, in accordance with various aspects and embodiments of the disclosed subject matter. The system 100 can be part of, employed by, or associated with a device (e.g., an electrical or electronic device) or devices that can perform desired electrical or electronic functions.

For example, the system 100 or a device comprising all or a portion of the system 100 can comprise amplifiers, transistors, capacitors, diodes (e.g., laser diode, light-emitting diode (LED), photodiode, or other type of diode or load circuit of a system operating as a current mode driver), voltage supply component(s), current source component(s), optical electronic component(s), and/or other electrical or electronic components that can be respectively arranged and/or connected to form an electrical circuit that can perform desired electrical or electronic functions. The system 100 can be utilized in, as part of, or in connection with a variety of different types of electronic devices, such as, for example, a receiver, a transmitter, a communication device (e.g., a phone, a mobile phone, a computer, a laptop computer, an electronic pad or tablet, a device that can provide high speed optical communications (e.g., which can be employed in datacenters or for other desired applications), a television, an Internet Protocol television (IPTV), a set-top box, an electronic gaming device, electronic eyeglasses with communication functionality, an electronic watch with communication functionality, other electronic bodywear with communication functionality, or Internet of Things (IoT) devices), optical-related or solar-related devices (e.g., solar cells, communication devices, communication network devices, or other type of electronic device that can employ optical electronic technology; lighting-related devices (e.g., LED devices, laser-related devices; optical-related memory device; or other type of lighting-related device that can employ optical electronic technology), or other type of optical-related or solar-related device), vehicle-related electronic devices, appliances (e.g., refrigerator, oven, microwave oven, washer, dryer, or other type of appliance), audio equipment (e.g., stereo system, radio system, or other type of audio equipment), musical equipment (e.g., electric or electronic musical instruments, instrument amplifier, audio signal processor, or other type of musical equipment), or other type of electronic device that can utilize an amplifier, a driver circuit, a diode, and/or other type of electrical or electronic component to facilitate operation of the electronic device.

The system 100 can comprise a driver circuit 102 that can be associated with (e.g., electrically and/or communicatively connected to) and can facilitate driving, controlling, or facilitating operation of a diode component 104. In accordance with various embodiments, the driver circuit 102 can be a current mode driver circuit or a VCSEL driver circuit. In some embodiments, the diode component 104 can be or can comprise a VCSEL diode.

The driver circuit 102 can comprise a regulator component 106 that can regulate a voltage to facilitate providing a desired regulated voltage (V_{reg}) for the driver circuit 102 based at least in part on a supply voltage provided by a voltage source 108 associated with the driver circuit 102. In some embodiments, the regulator component 106 can be a linear and low-dropout (LDO) regulator that can regulate a voltage (e.g., as an output from the regulator component 106) at a desired voltage level (e.g., a relatively lower voltage level) based at least in part on the supply voltage at a supply voltage level (e.g., a relatively higher voltage level) provided to the regulator component 106 and driver circuit 102. The output of the regulator component 106 can be associated with an anode 110 associated with the diode component 104 via a resistor component 112, which can have a desired resistance value (e.g., an equivalent or total resistance, rt).

In some embodiments, the regulator component 106 can comprise an amplifier component 114 and a transistor component 116, wherein a gate of the transistor component 116 can be connected to an output (e.g., output port) of the amplifier component 114. The transistor components 116 can be any type of transistor.

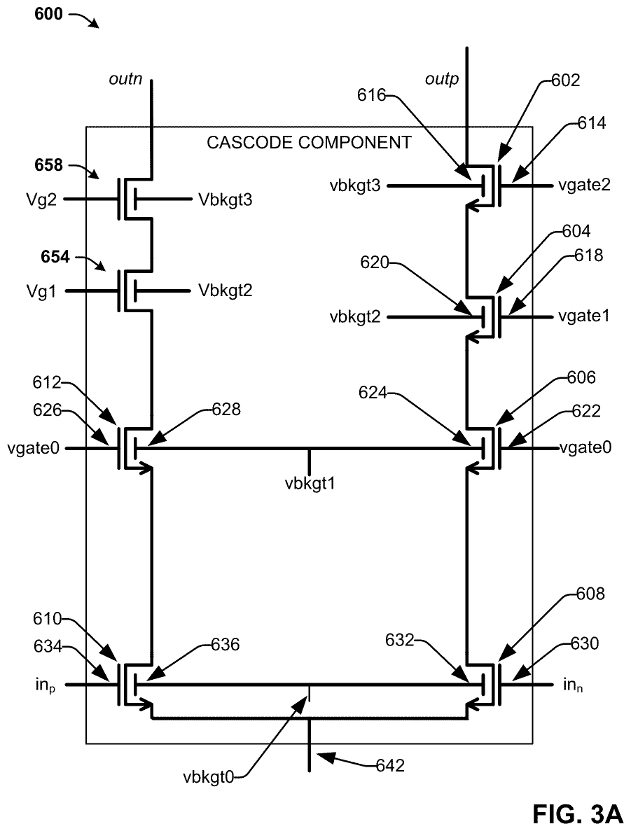

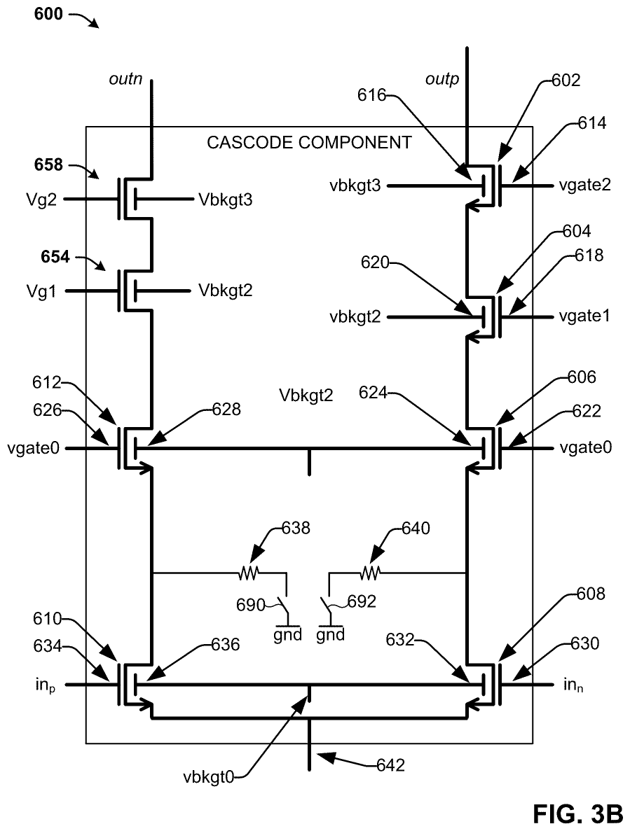

In accordance with various embodiments, the driver circuit 102 can comprise a desired number of cascode components, such as, for example, switching elements, 120. One exemplary configuration of cascode components is shown as element 600 in FIG. 3A. The cascode component 120 can comprise a desired number (e.g., 2, 3, 4, or more) of transistors that can be stacked in series and/or arranged in relation to each other such that respective gates of the respective transistors of the cascode components 120 can comprise, for example, gate 0, gate 1, and gate 2, wherein a gate voltage, e.g., vgate0, can be supplied to gate 0, a gate voltage, e.g., vgate1, can be supplied to gate 1, and a gate voltage, e.g., vgate2, can be supplied to gate 2. The respective backgates of the respective transistors of the cascode components 118 and 120 can comprise, for example, backgate 0, backgate 1, backgate 2, and backgate 3, wherein a backgate voltage, e.g., vbkgt0, can be supplied to backgate 0, a backgate voltage, e.g., vbkgt1, can be supplied to backgate 1, a backgate voltage, e.g., vbkgt2, can be supplied to backgate 2, and a backgate voltage, e.g., vbkgt3, can be supplied to backgate 3, such as described herein. Although designated as cascode components, any other arrangement is contemplated.

In one configuration, the outputs (e.g., outputs (outp)) of the cascode components 120 can be associated with the anode 110 and the resistor component 112. The output (e.g., output (outn)) of the cascode components 120 can be associated with a resistor component 122 that can be associated with the output of the regulator component 106, wherein the resistor component 122 can have a desired resistance value (e.g., an equivalent or total resistance, rt) that can be the same as the resistor component 112. In certain embodiments, the main current can be set to 0 mA during start-up mode though, if desired, and set to a desired main current level (e.g., a non-zero main current level) during mission mode.

The driver circuit 102 also can comprise a driver feedback loop 130 that can feedback (e.g., via a first feedback loop of the driver feedback loop 130) the electrical signal from the output of the regulator component 106 to an input (e.g., the negative terminal input) of the amplifier component 114 of the regulator component 106. The driver feedback loop 130 also can be associated with the anode 110 and the output (outp) associated with the outp-terminals of the cascode components 120, in addition with being associated with the output of the regulator component 106. The outputs outp and outn are shown in FIG. 3A and FIG. 3B. Within the switch module 120 are numerous instances of the sub-block shown in FIG. 3A and FIG. 3B. In one embodiment, there are 48 instances of the cascode switching module. When the driver circuit 102 is in mission mode, the driver feedback loop 130 can comprise a low pass filter component (LPF) 132 that can desirably filter (e.g., low pass filter) the feedback signal to the amplifier component 114.

In some embodiments, the driver circuit 102 can comprise a reference circuit that can comprise a resistor component 134, having a desired resistance (e.g., 12 rt or other desired resistance), that, on one end (e.g., port), can be associated with the output (V_{reg}) of the regulator component 106, and on another end, can be associated with a current source component 136 and a current source 138, wherein the current source component 136 can provide a scaled version of a bias current (e.g., ibias/12 or other scaled amount of bias current) to the driver circuit 102 (e.g., to the reference circuit of the driver circuit 102) and the current source 138 can provide a scaled version of the main current (e.g., im/24 or other scaled amount of the main current)) to the driver circuit 102 (e.g., to the reference circuit of the driver circuit 102). In some embodiments, the main current can be set to 0 mA during start-up mode. The amount of resistance (e.g., 12 rt or other desired resistance greater or less than 12 rt) of the resistor component 134 can be a desired factor (e.g., 12 or other desired factor greater than or less than 12) of the amount of resistance (e.g., rt) of the resistor component 112. The reference circuit can generate a reference current (I_{ref}) and a reference voltage (V_{ref}), based at least in part on the resistance (e.g., 12 rt) of the resistor component 134, the scaled version of the bias current (e.g., ibias/12), and the scaled version of the main current (e.g., im′/24). In certain embodiments, when the driver circuit 102 is in mission mode, the reference voltage (V_{ref}) is provided to the amplifier component 114 (e.g., the positive input terminal of the amplifier component 114) of the regulator component 106 via a low-pass filter (LPF) 132.

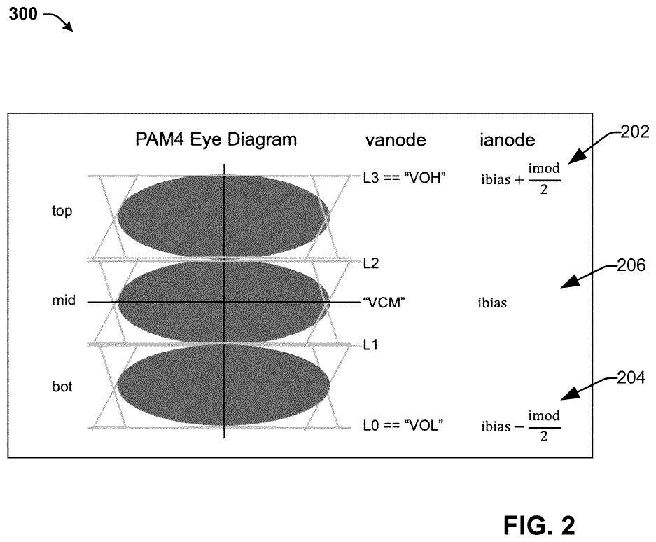

When the driver circuit 102 is in mission mode, the driver circuit 102 can switch between a VOL state (e.g., low state) and a VOH state (e.g., high state), wherein the driver circuit 102 can be in the VOL state when the main current, im, is supplied to the driver circuit 102 via the current mirror components 126 which supply modulation current, and wherein the driver circuit 102 can be in the VOH state when the main current, im, is at 0 mA. In the VOL state, the anode voltage (V_{anode}) at the anode 110 can be equal to VOL, and the anode current (I_{anode}) at the anode 110 can be equal to ibias-imod/2. In the VOH state, the anode voltage (V_{anode}) can be equal to VOH, and the anode current (I_{anode}) at the anode 110 can be equal to ibias+imod/2. The mission mode of the driver circuit 102 can have an implicit “VCM” state, which does not explicitly exist (e.g., because the driver is single ended and data is PAM4 with levels 0,1,2,3 and cannot be explicitly set to the mid-level code 1.5, the “VCM” level). The “VCM” state can be an average of the VOH and VOL states, and accordingly, the average anode current at the anode 110 can be equal to ibias (e.g., average anode current=((ibias+imod/2)+ (ibias-imod/2))/2). The driver circuit 102 can only be set to PAM4 levels L0, L1, L2, or L3, (as illustrated on FIG. 2) wherein VOL=level L0 and VOH=level L3. With regard to the driver circuit 102 and the “VCM” state, the reference current (I_{ref}) can be equal to ibias/12+im/24, such that a delta voltage ΔV can be equal to (ibias+im/2).rt through the resistor component 134 (12 rt resistor, which can be a reference resistor). This can be the same as a delta voltage ΔV driving the load (e.g., diode component 104) of the driver circuit 102. It should be noted that the divisors 12 and 24 for the elements 136, 138 are exemplary. In other embodiments other values may be used or different ratios may be established other than 1:2. It is preferred to maintain the following relationship for the value of rt: Iref*Rref=ibias*rt.

Referring briefly to FIG. 2 (along with FIG. 1A), FIG. 2 depicts a diagram of an example PAM4 eye diagram 200 relating to the driver circuit 102, in accordance with various aspects and embodiments. The example PAM4 eye diagram 200 indicates the anode voltages (V_{anode}) and anode currents (I_{anode}) at the anode 110 for different states of the driver circuit 102. At level L3, associated with the top eye of the PAM4 eye diagram 200, the anode voltage can be VOH and the anode current can be ibias+imod/2, as indicated at reference numeral 202. At level L0, associated with the bottom eye of the PAM4 eye diagram 200, the anode voltage can be VOL and the anode current can be ibias-imod/2, as indicated at reference numeral 204. Between levels L1 and L2, associated with the middle eye of the PAM4 eye diagram 200, the anode voltage can be “VCM” and the anode current can be ibias, as indicated at reference numeral 206.

With further regard to the modulation current, imod, imod can be equal to im. (rt/(rt+rv)), wherein im can be the main current, rt can be the resistance of the resistor component 112, and rv can be the resistance associated with the load (e.g., diode component 104) associated with the driver circuit 102. This basic relationship regarding imod and im can be utilized to define the switching current (e.g., Iₒᵤₜₚ=im at VOL state, and Iₒᵤₜₚ=0 mA at VOH state) of the driver circuit 102. It is noted that imod can be dependent on the internal resistance rt, which, in some embodiments, can be approximately equal to 40 ohms, nominal (although the internal rt can greater or less than 40 ohms in other embodiments), and rv ∈[50 ohms: 100 ohms] in normal operating mode can be dependent on the bias current, ibias (although, in other embodiments, rv can have a different amount of resistance). It can be desirable (e.g., wanted or necessary) to know rt and rv so that the desired im for the driver circuit 102 can be properly defined or determined.

As disclosed, during transient conditions, such as, for example, start up (e.g., power on or up), power down, or bias point modifications, associated with the driver circuit 102, it can be desirable (e.g., wanted, needed, required, or otherwise desired) to control levels of various voltages and currents associated with the driver circuit 102, including respective voltage levels of respective voltages applied to respective gates or respective backgates of the cascode components 120, the bias current, and/or the modulation current of the driver circuit 102. To that end, in accordance with various embodiments, the system 100 can comprise a start-up controller component 140 that can be associated with (e.g., electrically and communicatively connected to) the driver circuit 102, and can control levels of the various voltages and currents associated with the driver circuit 102, including the respective voltage levels of the respective voltages applied to the respective gates and/or the respective backgates of the cascode components 120, the bias current, and/or the modulation current of the driver circuit 102, during transient conditions associated with the driver circuit 102, and the setting of desired bias points.

In some embodiments, the driver circuit can operate in start-up mode and mission mode (e.g., a steady state or normal operating mode), as controlled by the start-up controller component 140. The start-up mode actually can relate to and be utilized for any transient condition (e.g., powering up or on, powering down, or modification of a target bias point) associated with the driver circuit 102. The start-up controller component 140 can comprise or be associated with a switch component 142 that can be associated with the regulator component 106 and the driver feedback loop 130. For instance, the switch component 142 can be associated with or situated (e.g., physically or logically situated) between the LPF 132 and the amplifier component 114. The switch component 142 can comprise switches, including switch 144, switch 146, switch 148, and switch 150, that can be utilized to facilitate switching (e.g., transitioning) the driver circuit 102 between the start-up mode and the mission mode.

The switch 144 can be associated with (e.g., electrically, communicatively, or logically connected to) the negative input terminal of the amplifier component 114 and an output (e.g., output port or terminal) of a DAC component 152 of the start-up controller component 140 to facilitate bypassing the other (e.g., the reference) loop (e.g., the separate or second feedback loop) of the driver feedback loop 130 and/or disconnecting this other loop from the positive input terminal of the amplifier component 114 and to facilitate supplying a start-up reference voltage (V_{ref_su}), which can be output from the DAC component 152, to the negative input terminal of the amplifier component 114, if and when the switch 144 is in an on or closed state during the start-up mode (and the switch 146 is in an off or open state during the start-up mode). The switch 146 can be associated with (e.g., electrically, communicatively, or logically connected to) the positive input terminal of the amplifier component 114 and the other (e.g., the reference) loop (e.g., the separate or second feedback loop) of the driver feedback loop 130 that can be associated with the resistor component 134 to facilitate applying the reference voltage (V_{ref}) to the amplifier component 114, if and when the switch 146 is in an on or closed state during the mission mode (and the switch 150 is in an off or open state during the mission mode). The switch 148 can be associated with (e.g., electrically, communicatively, or logically connected to) the negative input terminal of the amplifier component 114 and the output of the LPF 132 to facilitate connecting the amplifier component 114 to the anode 110 and the output of the regulator component 106 via the LPF 132, if and when the switch 148 is in an on or closed state during the mission mode (and the switch 144 is in an off or open state during the mission mode). The switch 150 can be associated with (e.g., electrically, communicatively, or logically connected to) the positive input terminal of the amplifier component 114 and the anode 110 and output of the regulator component 106 to facilitate bypassing the LPF 132 in the first feedback loop of the driver feedback loop 130 and/or disconnecting the LPF 132 of this first feedback loop from the negative input terminal of the amplifier component 114, if and when the switch 150 is in an on or closed state during the start-up mode (and the switch 148 is in an off or open state during the mission mode).

In some embodiments, the start-up controller component 140 also can comprise a comparator component 154 that can be associated with the output of the DAC component 152 and the other (e.g., the reference) loop (e.g., the separate or second feedback loop) of the driver feedback loop 130. For instance, the output of the DAC component 152 can be connected to the negative input terminal of the comparator component 154 to facilitate supplying the start-up reference voltage (V_{ref_su}) to the negative input terminal of the comparator component 154, and the other (e.g., the reference) loop (e.g., the separate or second feedback loop) of the driver feedback loop 130 can be connected to the positive input terminal of the comparator component 154 to facilitate supplying the reference voltage (V_{ref}) of the driver circuit 102 to the positive input terminal of the comparator component 154. During start-up mode, the comparator component 154 can compare the start-up reference voltage (V_{ref_su}) to the reference voltage (V_{ref}) to facilitate (e.g., enable) decisions or determinations by the start-up controller component 140 relating to controlling voltages and currents associated with the driver circuit 102, including the start-up reference voltage, the respective voltage levels of the respective voltages applied to the respective gates or the respective backgates of the cascode components 120, the bias current, and/or the modulation current of the driver circuit 102, during the start-up mode, such as described herein.

In some embodiments, the start-up controller component 140 can comprise DAC component 156 and DAC component 158 that each can comprise a desired number of DACs. The DAC component 156 can be associated with (e.g., electrically, communicatively, and/or logically connected to) the respective gates and respective backgates of the respective transistors of the cascode components 120 to facilitate controlling and supplying the respective voltages at the respective voltage levels to the respective gates and respective backgates of the respective transistors of the cascode components 120, such as described herein. The DAC component 158 can be associated with (e.g., electrically, communicatively, and/or logically connected to) the respective current mirror components, including current mirror/source components 126, 136, and 138, to facilitate controlling and supplying the respective currents (e.g., bias current (e.g., scaled bias current), main current (e.g., scaled main current), and/or respective portions of the main current) at the respective current levels to the respective current sink and current mirror components (e.g., 126, 136, and 138), such as described herein.

In accordance with various embodiments, the start-up controller component 140 can comprise a processor component 160 and a data store 162. The processor component 160 can be or can comprise one or more microcontrollers, controllers, microprocessors, and/or processors that can process data, control operations of other components of the start-up controller component 140 and/or the system 100, and/or perform various other functions, such as described herein. The processor component 160 can be associated with (e.g., electrically, communicatively, and/or logically connected to) the switch component 142, the DAC component 152, the comparator component 154, the DAC component 156, the DAC component 158, the data store 162, and/or other components of the start-up controller component 140 and/or the system 100, such as described herein. In one embodiment, the internal circuitry may be configured via a processor component through a serial interface between them. This may be achieved with a serial or parallel connection.

The data store 162 can comprise volatile memory, non-volatile memory, registers (e.g., storage registers), and/or other data storage that can be utilized to store data, such as data relating to operation or control of the driver circuit 102, the diode component 104, and/or the start-up controller component 140, such as described herein.

When the driver circuit 102 is going to be operated under a transient condition, such as startup (e.g., powering up or on) of the driver circuit 102, modification of operation of the driver circuit, or powering down or off of the driver circuit 102, the start-up controller component 140 can switch the switch component 142 to start-up mode. For instance, the processor component 160 can communicate an instruction signal (e.g., signal comprising an instruction, command, or code) to the switch component 142 (e.g., via a DAC associated with the switch component 142) to switch the switch component 142 to or maintain the switch component 142 in the start-up mode to have the driver circuit 102 operate in start-up mode.

During start-up of the driver circuit 102, and during each iteration of the start-up sequence employed in the start-up mode, the start-up controller component 140 can control voltage levels (e.g., vgate2, vgate1, vgate0; vbkgt3, vbkgt2, vbkgt1, vbkgt0) applied to respective gates or respective backgates of the respective transistors of the one or more cascode switch components 120 to maintain respective operating voltage levels associated with the respective transistors of the cascode switch components 120 at or below a defined voltage level (e.g., a threshold or threshold maximum operating voltage level) as the bias current level is incrementally increased to a target bias current level, a modulation current level is incrementally increased to a target modulation current level, and/or a start-up reference voltage level is incrementally increased to facilitate incrementally increasing an anode voltage level of an anode voltage of the anode 110 associated with the diode component 104. For instance, when the driver circuit 102 is in start-up mode, the driver feedback loop 130 of the driver circuit 102 can be reconfigured as a voltage follower such that the anode voltage level of the anode voltage (V_{anode}) of the anode 110 associated with the diode component 104 can track (e.g., be equal or substantially equal to) the start-up reference voltage level of the start-up reference voltage (V_{ref_su}) supplied to the regulator component 106 by the DAC component 152 of the start-up controller component 140, wherein the start-up reference voltage can be a programmable voltage that can be programmed or set by the start-up controller component 140 using the DAC component 152. This can allow the anode voltage level to be incrementally increased at the accuracy of the start-up reference voltage level, as the start-up reference voltage level is incrementally increased by the start-up controller component 140, in a DC manner. This can allow internal voltages of the driver circuit 102 to be desirably set (e.g., incrementally increased or decreased at each setting of the anode voltage target DAC setting) through an interface (parallel or serial) of the start-up controller component 140 without any time constraints. Likewise, the start-up controller component 140 can set reference currents, via internal DACs of the DAC component 158 of the start-up controller component 140, wherein the reference currents can set or facilitate setting the bias current, modulation current, and/or other types of currents of the driver circuit 102.

It is to be appreciated and understood that during respective iterations of the start-up sequence, the start-up controller component 140 can control and set respective voltage levels and/or respective current levels associated with the driver circuit 102, which can vary from iteration to iteration. For example, during a first iteration of the start-up sequence, where the start-up reference voltage (V_{ref_su}) is set to a first start-up reference voltage level, the start-up controller component 140 can control and set a first gate 2 voltage level for gate 2, a first gate 1 voltage level for gate 1, a first gate 0 voltage level for gate 0, a first backgate 3 voltage level for backgate 3, a first backgate 2 voltage level for backgate 2, a first backgate 1 voltage level for backgate 1, and/or a first backgate 0 voltage level for backgate 0 (e.g., first vgate2, first vgate1, first vgate0; first vbkgt3, first vbkgt2, first vbkgt1, first vbkgt0) that can be applied to the respective gates or the respective backgates of the respective transistors of the cascode switch components 120 to maintain the respective operating voltage levels associated with the respective transistors of the cascode components 118 and 120 at or below the defined voltage level (e.g., a threshold or threshold maximum operating voltage level). During a second iteration of the start-up sequence, where the start-up reference voltage (V_{ref_su}) has been incrementally increased by the start-up controller component 140 to a second start-up reference voltage level, the start-up controller component 140 can control and set a second gate 2 voltage level for gate 2, a second gate 1 voltage level for gate 1, a second gate 0 voltage level for gate 0, a second backgate 3 voltage level for backgate 3, a second backgate 2 voltage level for backgate 2, a second backgate 1 voltage level for backgate 1, and/or a second backgate 0 voltage level for backgate 0 (e.g., second vgate2, second vgate1, second vgate0; second vbkgt3, second vbkgt2, second vbkgt1, second vbkgt0) that can be applied to the respective gates or the respective backgates of the respective transistors of the cascode components 120 to maintain the respective operating voltage levels associated with the respective transistors of the cascode components 120 at or below the defined maximum voltage level. It is contemplated that the components 120 may be any number of transistors alone or in a stack cascode configuration.

During a particular iteration of the start-up sequence, the respective gate voltage levels that can be applied (e.g., by the start-up controller component 140 via the DAC component 156) to the respective gates, and the respective backgate voltage levels that can be applied to the respective backgates, of the respective transistors of the cascode components 120, and, accordingly, the respective codes (e.g., respective code settings) that can be applied to the respective DACs of the DAC component 156 can be dependent in part on, and can be determined (e.g., by the start-up controller component 140) based at least in part on, the bias current level of the bias current, the modulation current level of the modulation current, the start-up reference voltage level of the start-up reference voltage or start-up reference code associated with that start-up reference voltage level, and/or another factor (e.g., another characteristic, attribute, or property of or associated with the driver circuit 102). Also, during a particular iteration of the start-up sequence, the respective current levels of certain respective currents (e.g., reference bias current, main current, pre-emphasis current modulation (if employed), and/or other current) that can be set and applied (e.g., by the start-up controller component 140 via the DAC component 158) for the driver circuit 102, and, accordingly, the respective codes (e.g., respective code settings) that can be applied to respective DACs of the DAC component 158 can be dependent in part on, and can be determined (e.g., by the start-up controller component 140) based at least in part on, the bias current level of the bias current, the modulation current level of the modulation current, and/or another factor.

During startup of the driver circuit 102, the start-up controller component 140 (e.g., the start-up circuit of the start-up controller component 140) can enable a desirably controlled increase of the anode voltage associated with the anode 110 and internal node voltages of various nodes of the driver circuit 102. As the start-up reference voltage (V_{ref_su}) is increased by the start-up controller component 140, the diode component 104 can turn on, which can draw the anode current, I_{anode}, through the resistor component 112 (rt), which can cause the regulator voltage (V_{reg}) to increase and the reference voltage (V_{ref}) to increase, until the comparator component 154 trips (e.g., the comparator component switches from a 0 value to a 1 value at its output), which can occur when the anode current level is greater than the bias current level (I_{anode}>ibias). The reference voltage (V_{ref}) can be equal to the start-up reference voltage (V_{ref_su}) when the anode current level is equal to the bias current level. When the anode current level is greater than the bias current level (I_{anode}>ibias), the reference voltage can be greater than the start-up reference voltage (V_{ref}>V_{ref_su}), which can cause the comparator component 154 to trip.

During the start-up mode, the start-up controller component 140 (e.g., the processor component 160 of the start-up controller component 140) can set, program, or define a target bias current level and/or a target modulation current level (if setting of the modulation current is desired or required). The start-up controller component 140 also can set the bias current to an initial low (e.g., minimum) bias current level. For instance, with regard to the bias current, the processor component 160 can communicate an instruction signal (e.g., signal comprising instruction information or code) to the DAC component 158 to have a DAC of the DAC component 158 set the bias current to the initial low bias current level.

In some embodiments, the comparator component 154 can compare the reference voltage level (V_{ref}) of the driver circuit 102 to a start-up reference voltage level (V_{ref_su}), and can determine whether the reference voltage level is greater than the start-up reference voltage level based at least in part on the result of the comparison. If the reference voltage level is greater than the start-up reference voltage level, the comparator component 154 can trip (e.g., can switch from a 0 value to a 1 value at its output). If the reference voltage level is not greater than the (current) start-up reference voltage level, the comparator component 154 can remain untripped (e.g., can remain at 0 value at its output). At this initial point, typically, the comparator component 154 can be at a 0 value.

If the comparator component 154 determines that the reference voltage level is not greater than the start-up reference voltage level, the start-up controller component 140 can increment the start-up reference voltage level to a next (e.g., a next or incrementally higher) start-up reference voltage level. In some embodiments, the start-up controller component 140 can employ the processor component 160 to set or program a next start-up reference voltage code that can be applied to the DAC component 152, which can, based at least in part on the next start-up reference voltage code, supply the next start-up reference voltage at the next start-up reference voltage level to the driver circuit 102, wherein the next start-up reference voltage code can correspond or be mapped to the desired next start-up reference voltage level.

The start-up controller component 140, employing the processor component 160, can determine and set the respective gate voltage levels of the respective gates of the cascode components 120, the respective backgate voltage levels of the respective backgates of the cascode component 120, and the respective current levels associated with the driver circuit 102 (e.g., to be used during the next iteration of the start-up sequence) based at least in part on (e.g., corresponding to, or as mapped to) the next (now current) start-up reference voltage level. For instance, the processor component 160 can set or program respective codes that can be applied to respective DACs of the DAC component 156 that can, based at least in part on the respective codes, supply the respective gate voltages at the respective gate voltage levels (e.g., vgate2, vgate1, vgate0) to the respective gates and/or supply the respective backgate voltages at the respective backgate voltage levels (e.g., vbkgt3, vbkgt2, vbkgt1, vbkgt0) to the respective backgates of the respective transistors of the cascode components 120. The processor component 160 also can set or program respective codes that can be applied to respective DACs of the DAC component 158 that can, based at least in part on the respective codes, supply the respective currents (e.g., reference bias current, main current, and/or other type of current, such as described herein) at the respective current levels to the respective current mirror components (e.g., current mirror and source components 126, 136, and 138, and/or other current mirror component, such as described herein) of the driver circuit 102 (e.g., during the next iteration of the start-up sequence), in accordance with the next start-up reference voltage level, such as described herein. The respective codes can correspond or be mapped to the desired respective gate voltage levels, respective backgate voltage levels, and the respective current levels.

At this point, the start-up controller component 140 can determine whether the reference voltage level of the reference voltage generated by the driver circuit 102 is greater than the next (the now current) start-up reference voltage level of the next (the now current) start-up reference voltage supplied to the driver circuit 102 by the DAC component 152. For instance, the comparator component 154 can compare the reference voltage level (V_{ref}) of the driver circuit 102 to the current start-up reference voltage level (V_{ref_su}), and can determine whether the reference voltage level is greater than the current start-up reference voltage level based at least in part on the result of the comparison. If the reference voltage level is greater than the current start-up reference voltage level, the comparator component 154 can trip (e.g., can switch from a 0 value to a 1 value). If the reference voltage level is not greater than the current start-up reference voltage level, the comparator component 154 can remain untripped (e.g., can remain at 0 value). During each iteration of the start-up sequence, if the comparator component 154 determines that the reference voltage level is not greater than the current start-up reference voltage level, the start-up controller component 140, employing the processor component 160 (e.g., programming the DAC component 152), can increment the start-up reference voltage level to a next (e.g., a next or incrementally higher) start-up reference voltage level, such as described herein. The start-up controller component 140, employing the processor component 160, also can determine and set the respective gate voltage levels of the respective gates of the cascode components 120, the respective backgate voltage levels of the respective backgates of the cascode components 120, and the respective current levels associated with the driver circuit 102 (e.g., to be used during the next iteration of the start-up sequence) based at least in part on (e.g., corresponding to, or as mapped to) the next (now current) start-up reference voltage level, such as described herein. The start-up controller component 140 can continue to perform one or more iterations of the start-up sequence relating to incrementing the start-up reference voltage level, and setting the respective gate voltage levels, the respective backgate voltage levels, and the respective current levels, until the comparator component 154 determines that the reference voltage level (V_{ref}) is greater than the start-up reference voltage level (V_{ref_su}). If and when the reference voltage level is greater than the current start-up reference voltage level, the comparator component 154 can trip (e.g., can switch from a 0 value to a 1 value). The processor component 160 can receive that indicator (e.g., the 1 value), from the comparator component 154, that the reference voltage level is greater than the current start-up reference voltage level.

If the start-up controller component 140 determines that the reference voltage level is greater than the (current) start-up reference voltage level, the start-up controller component 140, employing the processor component 160, can determine whether bias current level (e.g., the instant bias current level of the current iteration of the start-up sequence) is at the target bias current level. For instance, the start-up controller component 140 can compare the instant (e.g., current) bias current level to the target bias current level to determine whether the instant bias current level is the same as the target bias current level.

If, based at least in part on the comparison results, the start-up controller component 140 determines that the instant bias current level is not at the target bias current level, the start-up controller component 140 (e.g., employing the processor component 160 and associated DAC of the DAC component 158) can increment the instant bias current level of the bias current to a next (e.g., an incrementally increased) bias current level, wherein the next bias current level can become the instant bias current level during a next iteration of the start-up sequence. At this point, the start-up controller component 140 can perform one or more further iterations of the start-up sequence relating to determining whether an instant bias current level (at each iteration of the start-up sequence) is at the target bias current level, and iteratively incrementing an instant bias current level to a next (e.g., a next instant) bias current level for a next iteration of the sequence if the start-up controller component 140 determines that the instant bias current level (of the instant iteration) is not at (e.g., is below) the target bias current level, until the start-up controller component 140 determines that an instant bias current level (of an iteration of the sequence) is at the target bias current level. During each of these iterations (e.g., relating to determining whether the bias current level is at the target bias current level and incrementing the bias current level if determined to not be at the target bias current level), after incrementing the bias current level to the next bias current level, the start-up controller component 140 can perform one or more iterations of determining whether the reference voltage level of the reference voltage generated by the driver circuit 102 is greater than the start-up reference voltage level (e.g., the current start-up voltage level) of the start-up reference voltage supplied to the driver circuit 102 by the DAC component 152; and, if the comparator component 154 determines that the reference voltage level is not greater than the start-up reference voltage level, the start-up controller component 140, employing the processor component 160, can increment the start-up reference voltage level to a next (e.g., a next or incrementally higher) start-up reference voltage level, and can determine and set (e.g., program) the respective gate voltage levels of the respective gates of the cascode components 120, the respective backgate voltage levels of the respective backgates of the cascode components 120, and the respective current levels associated with the driver circuit 102 (e.g., to be used during the next iteration of the start-up sequence) based at least in part on (e.g., corresponding to, or as mapped to) the next (now current) start-up reference voltage level, such as described herein. The start-up controller component 140 can perform these one or more iterations relating to incrementing the start-up reference voltage level, and setting the respective gate voltage levels, the respective backgate voltage levels, and the respective current levels (while the bias current is at the then-instant bias current level) until the comparator component 154 determines that the reference voltage level is greater than the start-up reference voltage level, wherein, after the comparator component 154 determines that the reference voltage level is greater than the start-up reference voltage level, the start-up controller component 140 can determine whether the instant bias current level satisfies (e.g., is at) the target bias current level.

If and when the start-up controller component 140 determines that an instant bias current level (of a particular iteration) is at the target bias current level, in some embodiments, the start-up controller component 140 can determine that the start-up of the driver circuit 102 is complete, and the processor component 160 can communicate an instruction signal (e.g., signal comprising an instruction, command, or code) to the switch component 142 (e.g., via a DAC associated with the switch component 142) to switch the switch component 142 from the start-up mode to the mission mode. For instance, if the start-up controller component 140 determines that an instant bias current level (of a particular iteration) is at the target bias current level, and setting or adjusting of a modulation current associated with the driver circuit 102 is not desired (e.g., not wanted or required), the start-up controller component 140 can determine that the start-up (or other transient condition) of the driver circuit 102 is complete, and the processor component 160 can communicate the instruction signal to the switch component 142 (e.g., via a DAC) to switch the switch component 142 from the start-up mode to the mission mode, and the driver circuit 102 can operate in mission mode from that point.

In other embodiments, if the start-up controller component 140 determines that an instant bias current level is at the target bias current level, and setting or adjusting of the modulation current associated with the driver circuit 102 is desired, the start-up controller component 140 can continue in the start-up mode to perform one or more iterations of the start-up sequence relating to adjusting (e.g., incrementing) the modulation current level from an initial modulation current level to a target modulation current level for the driver circuit 102. If the modulation current is to be set or adjusted during start-up (or other transient condition), the start-up controller component 140 (e.g., employing the processor component 160 and the DAC component 158) can set, program, or define the modulation current to an initial (e.g., a desired low) modulation current level. In some embodiments, the initial modulation current level can be 0 mA.

In some embodiments, if it is desired to power down the driver circuit 102, the start-up controller component 140 can switch the switch component 142 from mission mode to start-up mode, and, while in start-up mode, can perform essentially the same or similar operations of the iterative process of the start-up sequence relating to adjusting the bias current level (e.g., to the target bias current level) and/or adjusting the modulation current level (e.g., to the target modulation current level), except that the start-up controller component 140 can perform a power-down sequence, which essentially can be the start-up sequence in the reverse order, to iteratively and incrementally decrease the bias current level from the target bias current level to a zero or minimum bias current level and/or iteratively and incrementally decrease the modulation current level from the target modulation current level to a zero or minimum modulation current level. During the respective iterations, the start-up controller component 140 can incrementally decrease the start-up reference voltage level, while controlling application of the respective gate voltages to the respective gates of the cascode components 120, controlling application of the respective backgate voltages to the respective backgates of the cascode components 120, and controlling the application of the respective current levels to the driver circuit 102, such that the respective operating voltage levels of the respective transistors of the cascode components 120 can be maintained at or below the defined voltage level (e.g., a threshold or threshold maximum operating voltage level). In certain embodiments, during each iteration of the power-down sequence (e.g., the reverse-order of the start-up sequence) that corresponds to the same point in the start-up sequence (e.g., a point that can have the same bias current level, same modulation current level, and same start-up reference voltage level), although heading in the opposite direction, the start-up controller component 140 can utilize the same respective gate voltage levels associated with the respective gates of the cascode components 120, the same respective backgate voltage levels associated with the respective backgates of the cascode components 120, the same respective current levels associated with the driver circuit 102, and/or can utilize the same respective codes for programming the respective DACs of the respective DAC components (e.g., 152, 156, 158) with regard to the respective gate voltage levels, respective backgate voltage levels, and respective current levels associated with the driver circuit 102.

In other embodiments, during the power-down sequence, the start-up controller component 140 can utilize different gate voltage levels associated with the gates of the cascode components 120, different backgate voltage levels associated with the backgates of the cascode components 120, different current levels associated with the driver circuit 102, and/or different codes for programming the respective DACs of the respective DAC components (e.g., 152, 156, 158) with regard to the gate voltage levels, backgate voltage levels, and current levels associated with the driver circuit 102 than were used during the start-up sequence at the corresponding sequence point. However, such different values still can be desirably selected and utilized by the start-up controller component 140 such that the respective operating voltage levels of the respective transistors of the cascode components 120 still can be maintained at or below the defined voltage level (e.g., a threshold or threshold maximum operating voltage level).

In some embodiments, if, while operating in mission mode, it is desired to modify (e.g., adjust or change) a target bias current level associated with the driver circuit 102 to decrease the target bias current level to a lower target bias current level, the start-up controller component 140 can control the switch component 142 to switch from mission mode to start-up mode, and, in start-up mode, the start-up controller component 140 can perform essentially the same or similar iterative process of the power-down sequence (e.g., the reverse order of the start-up sequence), except that the start-up controller component 140 can start incrementally decreasing the bias current level from the target bias current level, and can perform one or more iterations relating to incrementally decreasing the bias current level until the bias current level is decreased from the target bias current level to the lower target bias current level. Once the modification to the lower target bias current level is determined to be reached, the start-up controller component 140 can control the switch component 142 to switch back from start-up mode to mission mode.

FIG. 1B illustrates a block diagram of a non-limiting example system that can desirably control incrementally adjusting a bias current to a target bias current level with divider components. As compared to FIG. 1A, identical elements are identified with identical reference numbers. Only the new aspects of FIG. 1B are discussed. Due to this potential issue regarding the input of the amplifier component 114, in certain embodiments, the driver circuit 102 can comprise divider component 356 (RDIV) and divider component 358 that can be part of each of the loops (e.g., the first feedback loop and the second (or reference) feedback loop) of the driver feedback loop 130. The divider component 356 and divider component 358 each can comprise circuitry that can be arranged to divide or scale the voltage (e.g., voltage divider including resistor components, source follower circuit, etc), to generate respective voltages at respective lower voltage levels that can be applied to the respective inputs of the amplifier component 114 and can be within the range of relatively lower voltages (e.g., the threshold minimum voltage level and the threshold maximum voltage level) that can be handled by the input of the amplifier component 114.

The divider component 356 and/or divider component 358 can desirably divide or scale the reference voltage (V_{ref}) and the anode voltage (V_{anode}) to respectively generate a divided or scaled reference voltage (V_{ref_div}) and a divided or scaled anode voltage (V_{anode}_div), wherein the scaled reference voltage can be input to the amplifier component 114 when the driver circuit 102 is in mission mode, and wherein the scaled reference voltage can be input to the comparator component 154 for comparison with a scaled start-up reference voltage, such as described herein. For example, if the input differential of the input of the amplifier component is 1.2 V<vgs<1.8 V, employing the divider component 356 and/or divider component 358, the reference voltage (V_{ref}) can be divided or scaled to generate a divided or scaled reference voltage (V_{ref_div}) that can be equal to 1.2 V+⅓ (V_{ref}-1.2 V), and the anode voltage (V_{anode}) can be divided or scaled to generate a divided or scaled anode voltage (V_{anode_div}) that can be equal to 1.2 V+⅓ (V_{anode}-1.2 V). In some embodiments, the start-up controller component 140 also can scale the start-up reference voltage level of the start-up reference voltage (V_{ref_su}) such that it can be within the range of relatively lower voltages (e.g., the threshold minimum voltage level and the threshold maximum voltage level) which cover the operating range of V_{anode_div} and that can be handled by the input of the amplifier component 114. For example, the start-up reference voltage (V_{ref_su}) with a programmable range [1.8V: 3.0V] can be scaled such that the start-up controller component 140 can generate a scaled start-up reference voltage (V_{ref_su_div}) with a programmable range [1.2V: 1.8V]. In certain embodiments, the DAC component 152 can be a lower voltage DAC that can operate at such relatively lower voltages that can correspond to the relatively lower voltage range that can be handled by the input of the amplifier component 114.

With further regard to the processor component 160, the processor component 160 can work in conjunction with the other components (e.g., the data store 162, the driver circuit 102, the diode component 104, or another component) to facilitate performing the various functions of the system (e.g., system 100, system 300, or other system described herein). The processor component 160 can employ one or more processors, microprocessors, controllers, or microcontrollers that can process data, such as information relating to input signals, output signals, amplifier components, comparator components, transistors, cascode components, diode components, loads, start-up sequences, power-down sequences, other transient condition-related sequences, start-up reference voltages, gate voltages, backgate voltages, other voltages, currents, sequence algorithms (e.g., start-up sequence algorithms, power-down algorithms, or other transient condition-related algorithms), signal or traffic flows, policies, protocols, interfaces, tools, and/or other information, to facilitate operation of the start-up controller component 140 or associated system (e.g., system 100, system 300, or other system described herein), as more fully disclosed herein, and control data flow between the start-up controller component 140 and other components (e.g., driver circuit 102, diode component 104, data store 162, or other component) associated with (e.g., connected to) the start-up controller component 140.

The data store 162 can store data structures (e.g., user data, metadata), code structure(s) (e.g., modules, objects, hashes, classes, procedures) or instructions, information relating to input signals, output signals, amplifier components, comparator components, transistors, cascode components, diode components, loads, start-up sequences, power-down sequences, other transient condition-related sequences, start-up reference voltages, gate voltages, backgate voltages, other voltages, currents, sequence algorithms (e.g., start-up sequence algorithms, power-down algorithms, or other transient condition-related algorithms), signal or traffic flows, policies, protocols, interfaces, tools, and/or other information, to facilitate controlling operations associated with the start-up controller component 140 or associated system (e.g., system 100, system 300, or other system described herein). In an aspect, the processor component 160 can be functionally coupled (e.g., through a memory bus) to the data store 162 in order to store and retrieve information desired to operate and/or confer functionality, at least in part, to the start-up controller component 140, the data store 162, the driver circuit 102, the diode component 104, or other component, and/or substantially any other operational aspects of the start-up controller component 140.

The data store 162 described herein can comprise volatile memory and/or nonvolatile memory, such as described herein. By way of example and not limitation, nonvolatile memory can include read only memory (ROM), programmable ROM (PROM), electrically programmable ROM (EPROM), electrically erasable ROM (EEPROM), or flash memory. Volatile memory can include random access memory (RAM), which can act as external cache memory. By way of example and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Memory of the disclosed aspects are intended to comprise, without being limited to, these and other suitable types of memory. In some embodiments, the data store 162 also can comprise registers (e.g., data registers) that can store data.

In some embodiments, the input of the amplifier component 114 may have a range of relatively lower voltages (e.g., a threshold minimum voltage level and a threshold maximum voltage level) that it can handle. For example, the input differential of the input of the amplifier component may be 1.2 V<vgs<1.8 V, wherein vgs can be the voltage at the input of the amplifier component 114, the threshold minimum voltage level at the input can be 1.2 V, and the threshold maximum voltage level at the input can be 1.8 V. However, the reference voltage level of the driver circuit 102 and/or the start-up reference voltage level can be higher than 1.8 V.

Referring to FIG. 3A (along with FIG. 1), FIG. 3A illustrates a diagram of an example cascode component 600 comprising transistors in a desired cascode arrangement, in accordance with various aspects and embodiments of the disclosed subject matter. The example cascode component 600 (e.g., which can be or correspond to the cascode component 120 of FIG. 1) can comprise transistors, including transistors 602, 604, 606 that can be stacked in (e.g., connected in) series to each other, such as depicted in FIG. 3A. The cascode component 600 also can comprise transistors 608 and 610, which can be a matching pair of transistors which act as a differential pair or differential switch, and at whose gates, inp 634 and inn 630, a differential modulation data signal is applied, wherein the transistor 608 can be on the outp-side of the cascode component 600 and can be associated with (e.g., electrically, communicatively, and/or logically connected to) the transistor 606, and wherein the transistor 610 can be on the outn of the cascode component 600. The cascode component 600 also can include a transistor 612 that can be on the outn-side of the cascode component 600 and can be associated with the transistor 610. The transistor 602 can provide the output signal (outp) on the outp-side of the cascode component 600, and the transistor 612 can provide the output signal (outn) on the outn-side of the cascode component 600. In some embodiments, the transistors 602, 604, 606, 608, 610, and/or 612 can be fine gate length CMOS transistors.

The transistor 602 can comprise a gate 614, which can be gate 2 of the cascode component 600 that can have a gate-2 voltage (vgate2) applied to it by the start-up controller component 140, and can comprise a backgate 616, which can be backgate 3 of the cascode component 600 that can have a backgate-3 voltage (vbkgt3) applied to it by the start-up controller component 140. The transistor 604 can comprise a gate 618, which can be gate 1 of the cascode component 600 that can have a gate-1 voltage (vgate1) applied to it by the start-up controller component 140, and can comprise a backgate 620, which can be backgate 2 of the cascode component 600 that can have a backgate-2 voltage (vbkgt2) applied to it by the start-up controller component 140. The transistor 606 can comprise a gate 622, which can be gate 0 of the cascode component 600 that can have a gate-0 voltage (vgate0) applied to it by the start-up controller component 140, and can comprise a backgate 624, which can be backgate 1 of the cascode component 600 that can have a backgate-1 voltage (vbkgt1) applied to it by the start-up controller component 140. The transistor 612 can comprise a gate 626, which also can be gate 0 of the cascode component 600 that can have the gate-0 voltage (vgate0) applied to it by the start-up controller component 140, and can comprise a backgate 628, which also can be backgate 1 of the cascode component 600 that can have the backgate-1 voltage (vbkgt1) applied to it by the start-up controller component 140.

The transistor 608 can comprise a gate 630, which can have an input signal (inn) applied to it, and can comprise a backgate 632, which can be backgate 0 of the cascode component 600 that can have the backgate-0 voltage (vbkgt0) applied to it by the start-up controller component 140. The transistor 610 can comprise a gate 634, which can have an input signal (inp) applied to it, and can comprise a backgate 636, which also can be backgate 0 of the cascode component 600 that can have the backgate-0 voltage (vbkgt0) applied to it by the start-up controller component 140. Additional transistors 654, 658 are shown in a stacked configuration and function similarly to transistors 602, 604.

FIG. 3B illustrates a diagram of an example cascode component comprising transistors in a desired cascode arrangement with resistors switchable to ground, in accordance with various aspects and embodiments of the disclosed subject matter. As shown in FIG. 3B, the cascode component 600 also can further comprise optional resistors 638 and 640, which can be associated with respective terminals of transistors 606, 608, 610, and 612, wherein the resistors 638 and 640 each can have a desired amount of resistance. Associated with each resistor 638, 640 as shown is a respective switch 690, 692 which may be opened or closed by a control signal from a processor or controller such as processor component 160. The connection of resistors 638 and 640 into the circuit with the switches provides an additional feature to increase current flow through the cascoded transistors thereby further reducing the risk of harming circuit components. Tying the resistors 638, 640 to ground will draw a minimum leakage current from cascode transistors to thereby reduce vdrain and vsource for voltage protection in the case of zero current node 642.

In reference to FIG. 3A and FIG. 3B the cascode component 600 can receive an electrical signal at the input 642 of the cascode component 600 that can be associated with (e.g., electrically, communicatively, and/or logically connected to) other respective terminals of transistors 608 and 610, wherein the electrical signal can comprise the main current and/or other desired current (e.g., pre-emphasis modulation current and post-emphasis modulation current).

At respective times when the driver circuit is in start-up mode or is under another transient condition, or when the driver circuit is in mission mode, respective gate voltages at respective gate voltage levels can be applied to the respective gates (e.g., 614, 618, 622, 626, 630, 634) of the respective transistors (e.g., 602, 604, 606, 608, 610, 612), respective backgate voltages at respective backgate voltage levels can be applied to the respective backgates (e.g., 616, 620, 624, 628, 632, 636) of the respective transistors, and/or respective currents at respective current levels can be supplied at the input 642 to facilitate controlling operation of the cascode component 600, including respective switching of the respective transistors between off state (e.g., open state) and on state (e.g., closed state), respective switching of the inp-switch 610 of the cascode component 600 between off state and on state, respective switching of the inn-switch 608 of the cascode component 600 between off state and on state, generating an output electrical signal (outp) that can be output from the outp-side of the cascode component 600, and/or generating an output electrical signal (outn) that can be output from the outn-side of the cascode component 600. Although only one instance of the circuit 600 is shown, there are numerous cascode cells 600 which, summed together to form the switched modulation current im.

Also, at respective times when the driver circuit is in start-up mode or is under another transient condition (e.g., during respective iterations or operations of the start-up sequence, power-down sequence, or other transient condition-related sequence), the start-up controller component 140 can determine, and can apply in a controlled manner, respective gate voltages at respective gate voltage levels to the respective gates (e.g., 614, 618, 622, 626, 630, 634) of the respective transistors (e.g., 602, 604, 606, 608, 610, 612), and respective backgate voltages at respective backgate voltage levels to the respective backgates (e.g., 616, 620, 624, 628, 632, 636) of the respective transistors, such that the respective operating voltages of the respective transistors can be maintained at or below the defined voltage level (e.g., the threshold or threshold maximum operating voltage level), such as described herein.

It is to be appreciated and understood that this arrangement of transistors in such cascode arrangement is an exemplary embodiment of forming an arrangement of transistors and/or forming a cascode component for a driver circuit. In other embodiments, the transistors can be arranged to form a desired circuit that can be utilized as an alternative embodiment of the driver circuit.

In some embodiments, components (e.g., driver circuit, diode component, cascode components, start-up controller component, power supplies, processor component, data store, and/or other component(s)) of a system of the systems (e.g., system 100, system 300, or other system) described herein can be formed on a single integrated circuit (IC) chip or die. In other embodiments, respective components of a system of the systems described herein can be formed on respective IC chips or dies.

The aforementioned systems and/or devices have been described with respect to interaction between several components. It should be appreciated that such systems and components can include those components or sub-components specified therein, some of the specified components or sub-components, and/or additional components. Sub-components could also be implemented as components communicatively coupled to other components rather than included within parent components. Further yet, one or more components and/or sub-components may be combined into a single component providing aggregate functionality. The components may also interact with one or more other components not specifically described herein for the sake of brevity, but known by those of skill in the art.

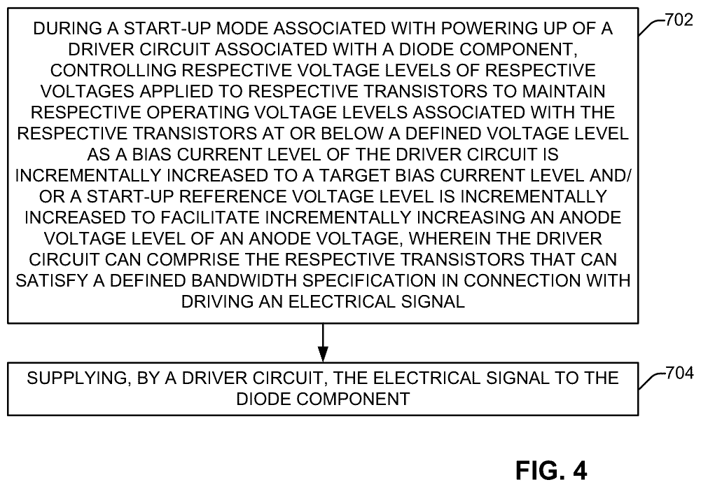

In view of the example systems and/or devices described herein, example methods that can be implemented in accordance with the disclosed subject matter can be further appreciated with reference to the flowcharts in FIG. 4 through FIG. 6. For purposes of simplicity of explanation, example methods disclosed herein are presented and described as a series of acts; however, it is to be understood and appreciated that the disclosed subject matter is not limited by the order of acts, as some acts may occur in different orders and/or concurrently with other acts from that shown and described herein. For example, a method disclosed herein could alternatively be represented as a series of interrelated states or events, such as in a state diagram. Moreover, interaction diagram(s) may represent methods in accordance with the disclosed subject matter when disparate entities enact disparate portions of the methods. Furthermore, not all illustrated acts may be required to implement a method in accordance with the subject specification. It should be further appreciated that the methods disclosed throughout the subject specification are capable of being stored on an article of manufacture to facilitate transporting and transferring such methods to computers for execution by a processor or for storage in a memory.

FIG. 4 illustrates a flow chart of an example method that can control incrementally increasing a bias current to a target bias current level for a driver circuit associated with a diode component during start-up of the driver circuit, in accordance with various aspects and embodiments of the disclosed subject matter. The method can be employed by or in connection with a system or device comprising a start-up controller component, the driver circuit, comprising a group of transistors, a DAC component, a processor component (e.g., a microcontroller, a microprocessor, a controller, or a processor), a data store or memory, and/or other electrical or electronic components or circuitry.

At step 702, during a start-up mode associated with powering up of a driver circuit associated with a diode component, respective voltage levels of respective voltages applied to respective transistors can be controlled to maintain respective operating voltage levels of operating voltages associated with the respective transistors at or below a defined voltage level as a bias current level of a bias current of the driver circuit is incrementally increased to a target bias current level and/or a start-up reference voltage level of a start-up reference voltage is incrementally increased to facilitate incrementally increasing an anode voltage level of an anode voltage associated with an anode associated with the diode component, wherein the driver circuit can comprise the respective transistors that can satisfy a defined bandwidth specification in connection with driving an electrical signal. In some embodiments, the respective transistors can comprise respective fine gate length CMOS transistors where some of the respective CMOS transistors can be arranged in series with (e.g., stacked with) other of the respective CMOS transistors to form respective cascode components, wherein the respective CMOS transistors can satisfy (e.g., meet or exceed) the defined bandwidth specification (e.g., bandwidth and speed specification or requirement) in connection with driving the electrical signal, such as described herein. In accordance with various embodiments, during respective iterations of incrementing of the start-up reference voltage level and/or the bias current level while in the start-up mode, the start-up controller component can control the respective voltage levels of the respective voltages applied to respective gates or respective backgates of the respective transistors to maintain the respective operating voltage levels associated with the respective transistors at or below the defined voltage level (e.g., 1.0V or other defined voltage level associated with desirable operation of the respective transistors) as at least the bias current level of the bias current of the driver circuit is incrementally increased to the target bias current level, such as described herein.

At step 704, the electrical signal can be supplied, by a driver circuit, to the diode component. The driver circuit can generate the electrical signal (e.g., output electrical signal) based at least in part on the bias current (e.g., bias current at the target bias current level) that can facilitate operation of the driver circuit. The driver circuit can supply the electrical signal to the diode component. In accordance with various embodiments, the driver circuit can be a current mode driver circuit, a VCSEL driver circuit, or other desired type of driver circuit.

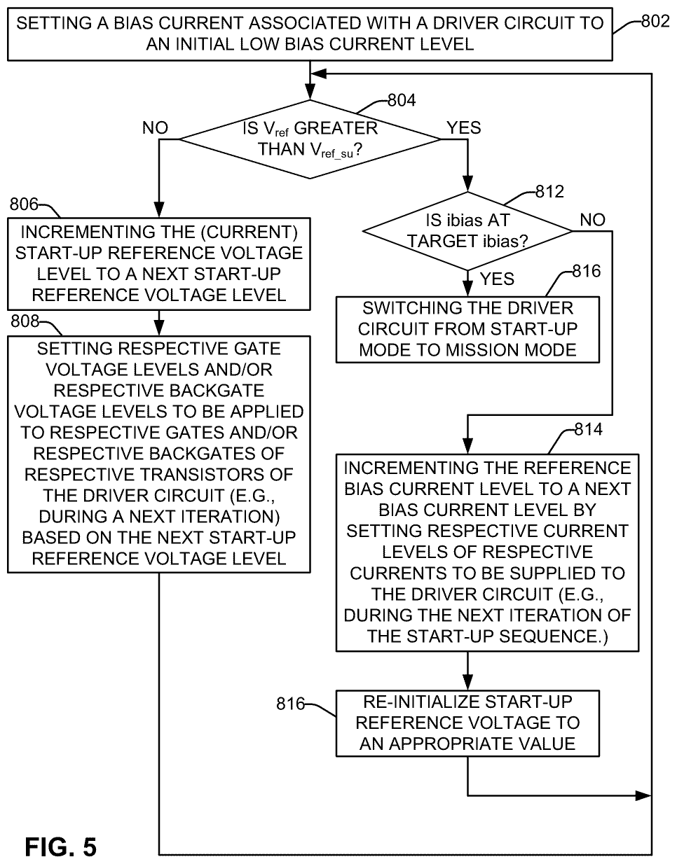

FIG. 5 depicts a flow chart of another example method that can control incrementally increasing a bias current to a target bias current level for a driver circuit associated with a diode component during start-up of the driver circuit, in accordance with various aspects and embodiments of the disclosed subject matter. The method can be employed by or in connection with a system or device comprising a start-up controller component, the driver circuit, comprising a group of transistors, a DAC component, a processor component (e.g., a microcontroller, a microprocessor, a controller, or a processor), a data store or memory, and/or other electrical or electronic components or circuitry.

At step 802, a bias current associated with a driver circuit can be set to an initial low bias current level. During a start-up mode utilized during start up or powering up of the driver circuit, the start-up controller component can set the bias current to the initial low (e.g., minimum) bias current level.

At step 804, a determination can be made regarding whether a reference voltage level of a reference voltage (V_{ref}) generated by the driver circuit is greater than a (current) start-up reference voltage level of a (current) start-up reference voltage (V_{ref_su}). The start-up controller component can comprise a comparator component that can compare the reference voltage level to the (current) start-up reference voltage level, and can determine whether the reference voltage level is greater than the (current) start-up reference voltage level based at least in part on the result of the comparison. If the reference voltage level is greater than the (current) start-up reference voltage level, the comparator component can trip (e.g., can switch from a 0 value to a 1 value). If the reference voltage level is not greater than the (current) start-up reference voltage level, the comparator component can remain untripped (e.g., can remain at 0 value).

At step 806, if it is determined that the reference voltage level is not greater than the (current) start-up reference voltage level, the (current) start-up reference voltage level can be incremented to a next start-up reference voltage level (which can become the (next or new) current start-up reference voltage level). The start-up controller component can increment the start-up reference voltage level to the next (e.g., and incrementally increased) start-up reference voltage level. In some embodiments, the start-up controller component can employ the processor component to set or program a next start-up reference voltage code that can be applied to a DAC that can, based at least in part on the next start-up reference voltage code, supply the next start-up reference voltage at the next start-up reference voltage level to the driver circuit, wherein the next start-up reference voltage code can correspond or be mapped to the desired next start-up reference voltage level.

At step 808, respective gate voltage levels of respective gate voltages and/or respective backgate voltage levels of respective backgate voltages to be applied to respective gates and/or respective backgates of respective transistors of the driver circuit (e.g., during a next iteration of the start-up sequence) can be set based at least in part on the next start-up reference voltage level. In some embodiments, the start-up controller component can employ the processor component to set or program respective codes that can be applied to respective DACs that can, based at least in part on the respective codes, supply the respective gate voltages at the respective gate voltage levels to the respective gates and/or the respective backgate voltages at the respective backgate voltage levels to the respective backgates of the respective transistors of the cascode component, in accordance with the next start-up reference voltage level, such as described herein. The respective codes can correspond or be mapped to the desired respective the respective gate voltage levels.

At this point, the method can proceed back to step 804, wherein the method can determine whether the reference voltage level of the reference voltage generated by the driver circuit is greater than the next (the now current) start-up reference voltage level of the next (the now current) start-up reference voltage, and the method can proceed from that point.

Referring again to step 804, if, instead, at step 804, it is determined that the reference voltage level is greater than the (current) start-up reference voltage level, at step 812, a determination can be made regarding whether the (current) bias current level is at the target bias current level. If the start-up controller component determines that the reference voltage level is greater than the (current) start-up reference voltage level, the start-up controller component can determine whether the (current) bias current level is at the target bias current level.

At step 814, if it is determined that the (current) bias current level is not at the target bias current level, then this method of operation will increment the reference bias current level to a next bias current level by setting respective current levels of respective currents to be supplied to the driver circuit (for example, during the next iteration of the start-up sequence. After step 814, the operation advances to a step 816. At a step 816 the system re-initializes the start-up reference voltage to an appropriate value. In one embodiment the start-up reference voltage is set to a minimum value or some value that is less the previous start-up reference voltage value to ensure that the comparator trip point will be seen in the next iteration.

At this point, the method can proceed back to step 804, wherein the method can determine whether the reference voltage level of the reference voltage generated by the driver circuit is greater than the next (the now current) start-up reference voltage level of the next (the now current) start-up reference voltage, and the method can proceed from that point.

Referring again to reference numeral 812, if, instead, at 812, it is determined that the bias current level is at the target bias current level, at 816, the driver circuit can be switched from start-up mode to mission mode. If the start-up controller component determines that the bias current level is at the target bias current level (and the comparator component has tripped for this setting because the reference voltage level was greater than the (current) start-up reference voltage level), the start-up controller component can switch the driver circuit from the start-up mode to the mission mode, such as described herein. From this point, the driver circuit can proceed to operate in the mission mode (e.g., normal or steady state mode).

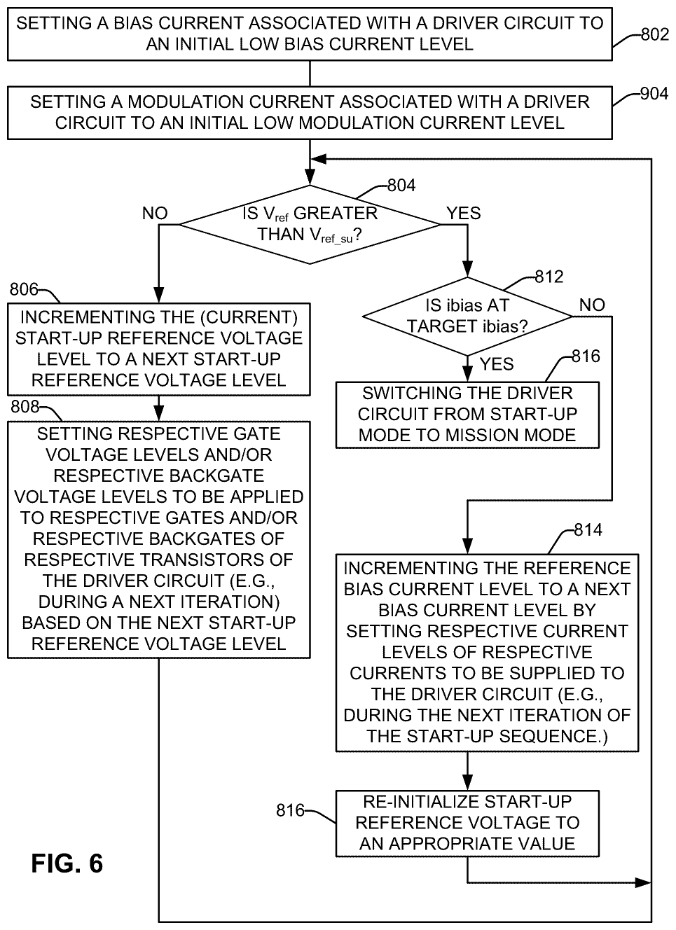

FIG. 6 illustrates a flow chart of an example method 900 that can establish a modulation current and a bias current to a target bias current level for a driver circuit associated with a diode component during start-up of the driver circuit, in accordance with various aspects and embodiments of the disclosed subject matter. FIG. 9. is generally similar to FIG. 5 and as such only the steps which differ from FIG. 5 are discussed. The method 900 can be employed by or in connection with a system or device comprising a start-up controller component, the driver circuit, comprising a group of transistors, a DAC component, a processor component (e.g., a microcontroller, a microprocessor, a controller, or a processor), a data store or memory, and/or other electrical or electronic components or circuitry.

In addition to the steps of FIG. 5, at a step 904, the system sets a modulation current associated with a driver circuit to an initial low modulation current level. During a start-up mode utilized during start up or powering up of the driver circuit, the start-up controller component can set the bias current to the initial low (e.g., minimum) bias current level and the modulation current to the initial low (e.g., minimum) modulation current level. In some embodiments, the initial low modulation current level can be zero mA. The remaining steps of FIG. 6 are the same as discussed and shown in FIG. 5 and as such are not discussed again.

Reference throughout this specification to “one embodiment,” “an embodiment,” “an example”, “a disclosed aspect,” or “an aspect” means that a particular feature, structure, or characteristic described in connection with the embodiment or aspect is included in at least one embodiment or aspect of the present disclosure. Thus, the appearances of the phrase “in one embodiment,” “in one example,” “in one aspect,” or “in an embodiment,” in various places throughout this specification are not necessarily all referring to the same embodiment. Furthermore, the particular features, structures, or characteristics may be combined in any suitable manner in various disclosed embodiments.

As utilized herein, terms “component,” “system,” “architecture,” “engine” and the like can refer to a computer or electronic-related entity, either hardware, a combination of hardware and software, software (e.g., in execution), or firmware. For example, a component can be one or more transistors, a memory cell, an arrangement of transistors or memory cells, a gate array, a programmable gate array, an application specific integrated circuit, a controller, a processor, a process running on the processor, an object, executable, program or application accessing or interfacing with semiconductor memory, a computer, or the like, or a suitable combination thereof. The component can include erasable programming (e.g., process instructions at least in part stored in erasable memory) or hard programming (e.g., process instructions burned into non-erasable memory at manufacture).

By way of illustration, both a process executed from memory and the processor can be a component. As another example, an architecture can include an arrangement of electronic hardware (e.g., parallel or serial transistors), processing instructions and a processor, which implement the processing instructions in a manner suitable to the arrangement of electronic hardware. In addition, an architecture can include a single component (e.g., a transistor, a gate array, or other component) or an arrangement of components (e.g., a series or parallel arrangement of transistors, a gate array connected with program circuitry, power leads, electrical ground, input signal lines and output signal lines, and so on). A system can include one or more components as well as one or more architectures. One example system can include a switching block architecture comprising crossed input/output lines and pass gate transistors, as well as power source(s), signal generator(s), communication bus(ses), controllers, I/O interface, address registers, and so on. It is to be appreciated that some overlap in definitions is anticipated, and an architecture or a system can be a stand-alone component, or a component of another architecture, system, device, or structure.

In addition to the foregoing, the disclosed subject matter can be implemented as a method, apparatus, or article of manufacture using typical manufacturing, programming or engineering techniques to produce hardware, firmware, software, or any suitable combination thereof to control an electronic device to implement the disclosed subject matter. The terms “apparatus” and “article of manufacture” where used herein are intended to encompass an electronic device, a semiconductor device, a computer, or a computer program accessible from any computer-readable device, carrier, or media. Computer-readable media can include hardware media, or software media. In addition, the media can include non-transitory media, or transport media. In one example, non-transitory media can include computer readable hardware media. Specific examples of computer readable hardware media can include but are not limited to magnetic storage devices (e.g., hard disk, floppy disk, magnetic strips, or other type of magnetic storage device), optical disks (e.g., compact disk (CD), digital versatile disk (DVD), or other type of optical disk), smart cards, and flash memory devices (e.g., card, stick, key drive, or other type of flash memory device). Computer-readable transport media can include carrier waves, or the like. Of course, those skilled in the art will recognize many modifications can be made to this configuration without departing from the scope or spirit of the disclosed subject matter.

What has been described above includes examples of the disclosed subject matter. It is, of course, not possible to describe every conceivable combination of components or methods for purposes of describing the disclosed subject matter, but one of ordinary skill in the art can recognize that many further combinations and permutations of the disclosed subject matter are possible. Accordingly, the disclosed subject matter is intended to embrace all such alterations, modifications and variations that fall within the spirit and scope of the disclosure. Furthermore, to the extent that a term “includes”, “including”, “has” or “having” and variants thereof is used in either the detailed description or the claims, such term is intended to be inclusive in a manner similar to the term “comprising” as “comprising” is interpreted when employed as a transitional word in a claim.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

It has proven convenient, principally for reasons of common usage, to refer to these signals as bits, values, elements, symbols, characters, terms, numbers, or the like. It should be borne in mind, however, that all of these and similar terms are to be associated with the appropriate physical quantities and are merely convenient labels applied to these quantities. Unless specifically stated otherwise or apparent from the foregoing discussion, it is appreciated that throughout the disclosed subject matter, discussions utilizing terms such as processing, computing, calculating, determining, or displaying, and the like, refer to the action and processes of processing systems, and/or similar consumer or industrial electronic devices or machines, that manipulate or transform data represented as physical (electrical and/or electronic) quantities within the registers or memories of the electronic device(s), into other data similarly represented as physical quantities within the machine and/or computer system memories or registers or other such information storage, transmission and/or display devices.

The various embodiments shown in the figures are exemplary only. These embodiments and configuration are not exhaustive of the numerous circuit layouts and configurations that may provide the disclosed benefits of safely incrementing bias current to a target bias current. There are numerous other configurations which are not shown, such as but not limited to powering down bias current or changing target bias current to a higher or lower target. Similarly, other methods of operation are possible which do not depart from the scope of the claims.

In regard to the various functions performed by the above described components, architectures, circuits, processes and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the embodiments. In addition, while a particular feature may have been disclosed with respect to only one of several implementations, such feature may be combined with one or more other features of the other implementations as may be desired and advantageous for any given or particular application. It will also be recognized that the embodiments include a system as well as a computer-readable medium having computer-executable instructions for performing the acts and/or events of the various processes.

What is claimed is:

1. A system that facilitates control of biasing of a driver circuit, comprising:
the driver circuit that controls an electrical signal supplied to a diode component, wherein the driver circuit comprises a group of transistors that satisfy a defined bandwidth specification in connection with driving the electrical signal; and
a start-up controller component that, during a start-up mode associated with powering up of the driver circuit, controls respective voltage levels of respective voltages applied to respective transistors of the group of transistors to have respective operating voltage levels of operating voltages associated with the respective transistors not be higher than a defined voltage level as at least a bias current level of a bias current of the driver circuit is incrementally increased to a target bias current level.

2. The system of claim 1, wherein the group of transistors comprises cascode connected transistors.

3. The system of claim 1, wherein the driver circuit comprises a regulator component associated with the start-up controller component and an anode associated with the diode component, wherein the driver circuit comprises driver feedback loop circuitry associated with the regulator component, wherein the start-up controller component supplies a start-up reference voltage to the regulator component, wherein, during the start-up mode, the driver feedback loop circuitry is configured as a voltage follower where an anode voltage level of an anode voltage associated with the anode is equivalent or substantially equivalent to a start-up reference voltage level of the start-up reference voltage as the start-up reference voltage level is incrementally increased, and wherein an anode bias current level of an anode bias current associated with the anode incrementally increases as the start-up reference voltage level is incrementally increased.

4. The system of claim 3, wherein, as the anode bias current level is incrementally increased, a regulator voltage level of a regulator voltage of the regulator component and a reference voltage level of a reference voltage generated by the driver circuit incrementally increase, and wherein the start-up controller component comprises a comparator component that compares the start-up reference voltage level to the reference voltage level and generates a comparison result based on the comparison of the start-up reference voltage level to the reference voltage level.

5. The system of claim 4, wherein, in response to the comparison result indicating that the reference voltage level is not greater than the start-up reference voltage level, the start-up controller component incrementally increases the start-up reference voltage level to a next start-up reference voltage level, adjusts the respective voltage levels of the respective voltages applied to respective gates or backgates of the respective transistors based on the next start-up reference voltage level, and incrementally increases a reference bias current level of a reference bias current to a next reference bias current level.

6. The system of claim 4, wherein, in response to the comparison result indicating that the reference voltage level is greater than the start-up reference voltage level, the start-up controller component determines that the anode bias current level is greater than the bias current level of the bias current, and determines whether the bias current level is at the target bias current level.

7. The system of claim 6, wherein, based on a determination that the bias current level is not at the target bias current level, the start-up controller component increments the bias current level to a next bias current level, and wherein the comparator component compares a next start-up reference voltage level to a next reference voltage level to facilitate determining whether the next reference voltage level is greater than the next start-up reference voltage level.

8. The system of claim 6, wherein, based on a determination that the bias current level is at the target bias current level and the comparison result indicating that the reference voltage level is greater than the start-up reference voltage level, the start-up controller component switches from the start-up mode to a mission mode to facilitate operation of the driver circuit, in the mission mode, at the target bias current level.

9. The system of claim 8, wherein switching from start-up mode to mission mode comprises opening two switches and closing two switches.

10. The system of claim 9, wherein, in response to determining that the bias current level is at the target bias current level, and the comparison result indicating that the reference voltage level is greater than the start-up reference voltage level, the start-up controller component switches from the start-up mode to a mission mode to facilitate operation of the driver circuit, in the mission mode, at the target bias current level and the target modulation current level.

11. The system of claim 9, wherein, in response to determining that, the start-up controller component incrementally increases the modulation current level, while the start-up controller component controls the respective voltage levels of the respective voltages applied to the respective transistors to have the respective voltage levels not be higher than the defined voltage level based on a stored look-up-table of maximum VOH vs modulation current for a given ibias and vcsel diode resistance.

12. The system of claim 3, wherein the start-up controller component comprises:
a first group of digital-to-analog converter components that, during respective iterations of incrementing of the start-up reference voltage level or incrementing of the bias current level, supply the respective voltages at the respective voltage levels to respective gates or respective back gates of the respective transistors, based on respective first code values applied to the first group of digital-to-analog converter components, to facilitate maintaining the respective operating voltage levels associated with the respective transistors at or below the defined voltage level; and
a second group of digital-to-analog converter components that, during the respective iterations, supply, via the driver circuit, respective currents, comprising the bias current, at respective current levels, based on respective second code values applied to the second group of digital-to-analog converter components, to facilitate operation of the driver circuit and the diode component.

13. The system of claim 1, wherein the driver circuit is a current mode driver circuit that controls the electrical signal supplied to the diode component.

14. A method that facilitates controlling biasing of a driver circuit, comprising:
during a start-up mode associated with powering up of the driver circuit, controlling respective voltage levels of respective voltages applied to respective transistors to maintain respective operating voltage levels of operating voltages associated with the respective transistors at or below a defined voltage level as at least a bias current level of a bias current of the driver circuit is incrementally increased to a target bias current level, wherein the driver circuit comprises the respective transistors that satisfy a defined bandwidth specification in connection with driving an electrical signal; and
supplying, by the driver circuit, the electrical signal to a diode component.

15. The method of claim 14, wherein the controlling further comprises: during the start-up mode, controlling the respective voltage levels of the respective voltages applied to the respective transistors to maintain the respective operating voltage levels of the operating voltages associated with the respective transistors at or below the defined voltage level as the bias current level of the bias current of the driver circuit is incrementally increased to the target bias current level and a start-up reference voltage level of a start-up reference voltage is incrementally increased to facilitate incrementally increasing an anode voltage level of an anode voltage associated with an anode associated with the diode component.

16. The method of claim 15, further comprising:
during respective iterations of incrementing of the start-up reference voltage level or incrementing of the bias current level, supplying the respective voltages at the respective voltage levels to respective gates or respective back gates of the respective transistors, based on respective first code values applied to a first group of digital-to-analog converter components associated with the driver circuit, to facilitate maintaining the respective operating voltage levels associated with the respective transistors at or below the defined voltage level; and
during the respective iterations, supplying, via the driver circuit, respective currents, comprising the reference bias current, at respective current levels, based on respective second code values applied to a second group of digital-to-analog converter components associated with the driver circuit, to facilitate operation of the driver circuit and the diode component.

17. The method of claim 14, further comprising:
in response to determining that at least one of the bias current levels is at the target bias current level, switching from the start-up mode to a mission mode to facilitate operating the driver circuit in the mission mode.

18. A non-transitory machine-readable medium, comprising executable instructions that, when executed by a processor, facilitate performance of operations, comprising:
during a start-up mode associated with powering up of a driver circuit, managing respective voltage levels of respective voltages applied to the respective transistors to maintain respective operating voltage levels of operating voltages associated with the respective transistors at or less than a defined threshold voltage level as a bias current level of a bias current of the driver circuit is incrementally increased to a target bias current level or a start-up reference voltage level of a start-up reference voltage is incrementally increased to facilitate incrementally increasing an anode voltage level of an anode voltage associated with an anode associated with the diode component, wherein the driver circuit comprises the respective transistors that satisfy a defined bandwidth specification in connection with driving an electrical signal; and
supplying, by the driver circuit, the electrical signal to a diode component.

19. The non-transitory machine-readable medium of claim 18, wherein the operations further comprise:
during respective iterations of incrementing of the start-up reference voltage level or incrementing of the bias current level, supplying the respective voltages at the respective voltage levels to respective gates or respective back gates of the respective transistors, based on respective first code values applied to a first group of digital-to-analog converter components associated with the driver circuit, to facilitate maintaining the respective operating voltage levels associated with the respective transistors at or less than the defined threshold voltage level; and
during the respective iterations, supplying, via the driver circuit, respective currents, comprising the bias current, at respective current levels, based on respective second code values applied to a second group of digital-to-analog converter components associated with the driver circuit, to facilitate operation of the driver circuit and the diode component.

20. The non-transitory machine-readable medium of claim 18, wherein the operations further comprise:
in response to determining that at least one of the bias current level is at the target bias current level, transitioning from the start-up mode to a mission mode to facilitate operating the driver circuit in the mission mode.

21. The non-transitory machine-readable medium of claim 18, wherein the operations further comprise providing control signals to two or more switches which establish a path to ground through a resistor for a minimum leakage current from cascode connected transistors to reduce drain voltage, source voltage, or both for voltage protection.

22. The system of claim 2, further comprising two or more switches which establish a path to ground through a resistor for a minimum leakage current from the cascode connected transistors to reduce drain voltage, source voltage, or both for voltage protection.
